(19) United States
(12) Patent Application Publication
(10) Pub. No.: US 2001/0025968 A1
(43) Pub. Date: Oct. 4, 2001

(54) Complementary MOS semiconductor device and method of manufacturing the same

(76) Inventor: Jun Osanai, Chiba-shi (JP)

Correspondence Address: ADAMS & WILKS, 31st Floor, 50 Broadway, New York, NY, 10004, US

(21) Appl. No.: 09/778,239

(22) Filed: Feb. 7, 2001

(30) Foreign Application Priority Data
Mar. 31, 2000 (JP) 2000-098575
May 10, 2000 (JP) 2000-137588
Sep. 28, 2000 (JP) 2000-296057

(51) Int. Cl. H01L 27/10; H01L 23/58

(52) U.S. Cl. 257/204

(57) ABSTRACT

In a CMOS semiconductor in which a lower withstand voltage CMOS and a higher withstand voltage CMOS are mixed together, all of characteristics including a temperature characteristic and an AC characteristic have a compatibility with the CMOS using a p-type semiconductor substrate, and a lead connecting a tab at the time of packaging a chip is formed into a Vdd terminal. With the structure and manufacturing method in which relatively thick p-type epitaxial layer is formed on an n-type semiconductor substrate, and a CMOS is formed on the p-type epitaxial layer, the conventional CMOS technique can be applied as it is, and the lead connected to the tab can be formed into the Vdd terminal.

### BACKGROUND OF THE INVENTION

1. Field of the Invention

The present invention relates to a complementary MOS semiconductor device that eliminates the limit of a power supply pin arrangement of a package and a method of manufacturing the same.

2. Description of the Related Art

FIG. 5 shows a cross-sectional view of a conventional semiconductor device in which a lower withstand voltage CMOS and a higher withstand voltage CMOS are mixed together. A lower withstand voltage MOS is of a so-called single drain structure using a p-type semiconductor substrate, and a lower withstand voltage NMOS is formed in a p-type semiconductor substrate, and a lower withstand voltage PMOS is formed in an n well formed in the p-type semiconductor substrate. On the other hand, in a higher withstand voltage MOS, in order to enhance a withstand voltage, it is necessary to form a drain by diffusion which is a low concentration. In the higher withstand voltage NMOS, in order to form a high withstand voltage element without adding any process, an n-well is used as a drain. This structure has advantages in that not only an additional process is not required, but also because the n-well is a relatively deep diffusion, a heat capacity is large, and in particular, when this semiconductor device is used as an output element, electrostatic discharge (hereinafter referred to as “ESD”) resistance is high. The reasons why the p-type semiconductor substrate is used as a starting material resides in that the employment of the above-mentioned higher withstand voltage NMOS structure is liable to ensure the ESD resistance, and also the costs for substrate are low as compared with the n-type semiconductor substrate.

However, in the conventional structure, when the semiconductor is packaged, in particular, in a standard package, the semiconductor substrate adheres to a tab using an adhesive having a conductivity such as a silver paste. Therefore, in the case of using the p-type semiconductor substrate, there arises such a problem in that a lead connected to the tab is naturally limited to a Vss terminal, and a user's demand who desires to use the Vdd terminal as the pin arrangement cannot be readily satisfied from the viewpoints of a board or module design. There is a method in which a specific tab is used and a packaging process is also changed to respond to the user's demand specification. However, in this case, the costs increase.

As another countermeasure, there is a method in which a CMOS is structured by using an n-type semiconductor substrate. However, in the drain of an NMOS of the higher withstand voltage CMOS, it is necessary to deepen the depth of a diffusion layer to some degree. In this case, it is essential to form a p-well which is deeper than the diffusion layer, which requires a heat treatment at a high temperature and for a long period of time, leading to an increase in the costs and an increase in a manufacturing period.

Also, even if the problems on the above-mentioned costs and manufacturing period are overcome using the n-type semiconductor substrate, a constant and a parameter value necessary for a circuit design or a product design cannot be completely identical with those in the case of using the p-type semiconductor substrate, and therefore it is impossible that all the characteristics of the product including the temperature characteristic and the AC characteristic are completely compatible with those in the case of using the p-type semiconductor substrate, with the result that the user's demand, which desires a product entirely identical in various characteristics but different in only the arrangement of a power supply pin, cannot be satisfied.

In addition, the above problem exists in not only the product structured by not only the CMOS where the higher withstand voltage and the lower withstand voltage are mixed together, but also in a product structured by only the lower withstand voltage CMOS.

### SUMMARY OF THE INVENTION

An object of the present invention is to eliminate the above problems.

In order to achieve the above objects, according to the present invention, there is provided a complementary MOS semiconductor device, comprising: an inverse conductive type semiconductor layer disposed on a one conductive type semiconductor substrate; a one conductive type deep diffusion layer formed in the inverse conductive type semiconductor layer; a one conductive type MOS transistor formed in the inverse conductive type semiconductor layer; and an inverse conductive type MOS transistor formed in the one conductive type deep diffusion layer.

Also, according to the present invention, there is provided a complementary MOS semiconductor device, comprising: an inverse conductive type semiconductor layer disposed on a one conductive type semiconductor substrate; a one conductive type deep diffusion layer formed in the inverse conductive type semiconductor layer; a one conductive type MOS transistor which is low in withstand voltage and formed in the inverse conductive type semiconductor layer; an inverse conductive type MOS transistor formed in the one conductive type deep diffusion layer; and a one conductive type MOS transistor which is high in withstand voltage and a source or a drain of which is structured by the one conductive type deep diffusion layer.

Further, according to the present invention, there is provided the complementary MOS semiconductor device further comprising: an inverse conductive type MOS transistor which is low in withstand voltage; and an inverse conductive type MOS transistor which is high in withstand voltage, both being formed in the one conductive type deep diffusion layer.

Still further, according to the present invention, there is provided the complementary MOS semiconductor device, wherein: the one conductive type semiconductor substrate is electrically connected to the one conductive type deep diffusion layer in which the inverse conductive type MOS transistor is formed; and the inverse conductive type layer has such a thickness that a depletion layer extending from the one conductive type deep diffusion layer to the inverse conductive type semiconductor layer is out of contact with a depletion layer extending from the one conductive type substrate to the inverse conductive type semiconductor layer during the operation of the semiconductor device.

Yet still further, according to the present invention, there is provided a method of manufacturing a complementary MOS semiconductor device, comprising the steps of: forming an inverse conductive type semiconductor layer on a one conductive type semiconductor substrate; forming a one conductive type deep diffusion layer in the inverse conductive type semiconductor layer; forming a one conductive type MOS transistor in the inverse conductive type semiconductor layer; and forming an inverse conductive type MOS transistor in the one conductive type deep diffusion layer.

Yet still further, according to the present invention, there is provided a method of manufacturing a complementary MOS semiconductor device, comprising the steps of: forming an inverse conductive type semiconductor layer on a one conductive type semiconductor substrate; forming a one conductive type deep diffusion layer in the inverse conductive type semiconductor layer; forming a one conductive type MOS transistor which is low in withstand voltage in the inverse conductive type semiconductor layer; forming an inverse conductive type MOS transistor in the one conductive type deep diffusion layer; and forming a source or a drain of a one conductive type MOS transistor which is high in withstand voltage, in said inverse conductive semiconductor layer by said one conductive type deep diffusion layer.

Yet still further, according to the present invention, there is provided the method of manufacturing a semiconductor device, wherein the inverse conductive semiconductor layer is formed through an epitaxial growth, to have an impurity concentration of from 1×10¹⁴/cm³ to 5×10¹⁵/cm³ and a thickness of from 20 to 50 μm.

### BRIEF DESCRIPTION OF THE DRAWINGS

These and other objects, features and advantages of this invention will become more fully apparent from the following detailed description taken with the accompanying drawings in which:

FIG. 1 is a schematic cross-sectional view showing a semiconductor device in accordance with a first embodiment of the present invention;

FIGS. 2A and 2B are schematic cross-sectional view showing the appearance of packaging the semiconductor device in accordance with the present invention;

FIG. 3 is a schematic cross-sectional view showing a semiconductor device in accordance with a second embodiment of the present invention;

FIGS. 4A to 4C are cross-sectional views showing a method of manufacturing a semiconductor device in accordance with the first embodiment of the present invention in a process order; and

FIG. 5 is a schematic cross-sectional view showing an example of a conventional semiconductor device.

### DETAILED DESCRIPTION OF THE PREFERRED EMBODIMENTS

Now, a description will be given in more detail of preferred embodiments of the present invention with reference to the accompanying drawings.

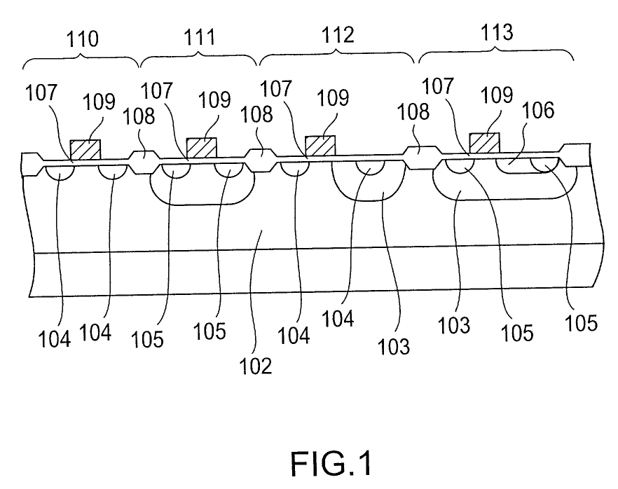

FIG. 1 is a schematic cross-sectional view showing a semiconductor device in accordance with a first embodiment of the present invention. FIG. 1 shows an example of a semiconductor device in which a lower withstand voltage CMOS and a higher withstand voltage CMOS are mixed together.

In the semiconductor device shown in FIG. 1, an n-type semiconductor substrate 101 is used, and a p-type semiconductor layer 102 is formed on the n-type semiconductor substrate 101 through epitaxial growth. A lower withstand voltage NMOS 110 is formed in the p-epitaxial layer 102, and PMOSs 111 and 113 are formed in an n-well 103 formed in the p-epitaxial layer 102. In addition, in order to enhance the withstand voltage, a higher withstand voltage PMOS 113 has a drain which is made up of a p-type diffusion 106 low in impurity concentration and a p+type diffusion 105 high in concentration. On the other hand, in order to enhance the higher withstand voltage and in order to enhance the resistance, the higher withstand voltage NMOS 112 uses the n-well 103 as a drain.

The structure of the lower withstand voltage MOS is based on a so-called single drain structure, and in case of a fine MOS, a structure using a drain engineering method such as an LDD (lightly doped drain) may be applied to the structure of the lower withstand voltage MOS.

A semiconductor manufacturing method will be described later, but the essence of the present invention is directed to the followings: A p-epitaxial layer having the same impurity concentration as that of the conventional p-type semiconductor substrate is disposed on an n-type semiconductor substrate, and in the subsequent manufacturing processes, the conditions for a manufacturing process of forming a CMOS are used as they are, in which a lower withstand voltage CMOS and a higher withstand voltage CMOS are mixed together by using the conventional p-type semiconductor substrate, thereby being capable of making the respective element characteristics identical with those in the case of using the p-type semiconductor substrate, with the result that all the characteristics of the semiconductor device including the temperature characteristic and the AC characteristic can provide the complete compatibility with those in the case of using the conventional p-type semiconductor substrate.

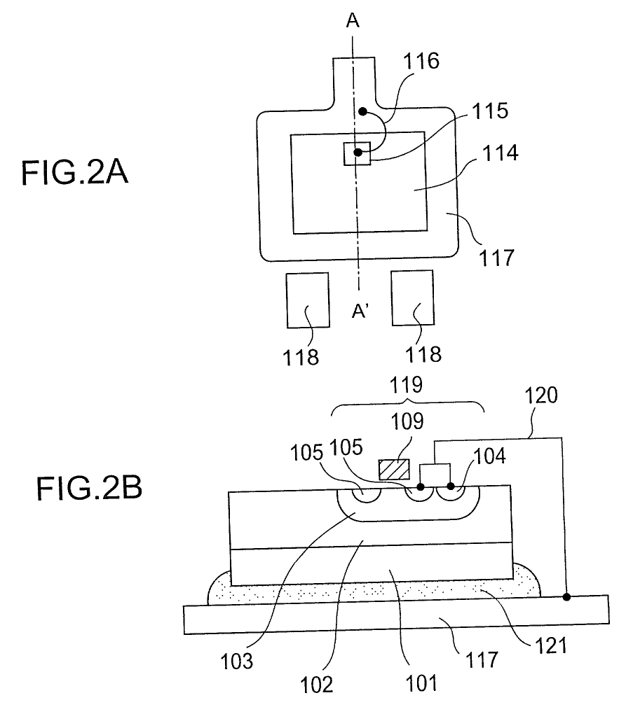

Then, the operation of the present invention will be described with reference to FIGS. 2A and 2B. FIG. 2A is a plan view showing the appearance of mounting a semiconductor device in accordance with the present invention. A semiconductor chip 114 with the structure of the present invention is located on a tab 117, and a Vdd terminal of the chip and the tab are electrically connected to each other by a bonding wire 116. Also, FIG. 2B shows the appearance of a section taken along a line A-A′ of FIG. 2A. The chip adheres to the tab 117 by an adhesive 121 having the conductivity, and the n-type semiconductor substrate 101 is electrically connected to the tab 117, and there is no problem on the operation of the semiconductor device by using as the Vdd pin the lead connected to the tab. Therefore, the lead connected to the tab can be formed into the Vdd terminal while the CMOS formation technique using as the starting material the p-type semiconductor substrate and the characteristic of the semiconductor device formed through that technique are kept completely identical.

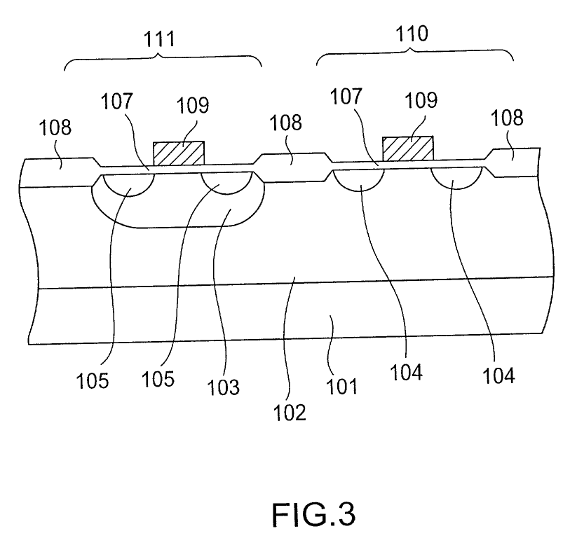

FIG. 3 is a schematic cross-sectional view showing a semiconductor device in accordance with a second embodiment of the present invention. FIG. 3 shows a case in which the semiconductor device is made up of only a lower withstand voltage CMOS.

In the semiconductor device shown in FIG. 3, an n-type semiconductor substrate 101 is used, and a p-type semiconductor layer 102 is formed on the n-type semiconductor substrate 101. A lower withstand voltage NMOS 110 is formed in the p-epitaxial layer 102, and a PMOS 111 is formed in an n-well 103 formed in the p-epitaxial layer 102.

The semiconductor device according to the second embodiment is made identical with that according to the first embodiment shown in FIG. 1 so that the lead pin connected to the tab can be formed into the Vdd terminal through a normal packaging method while the characteristic of the semiconductor device is entirely identical with that of the characteristic using the p-type semiconductor substrate.

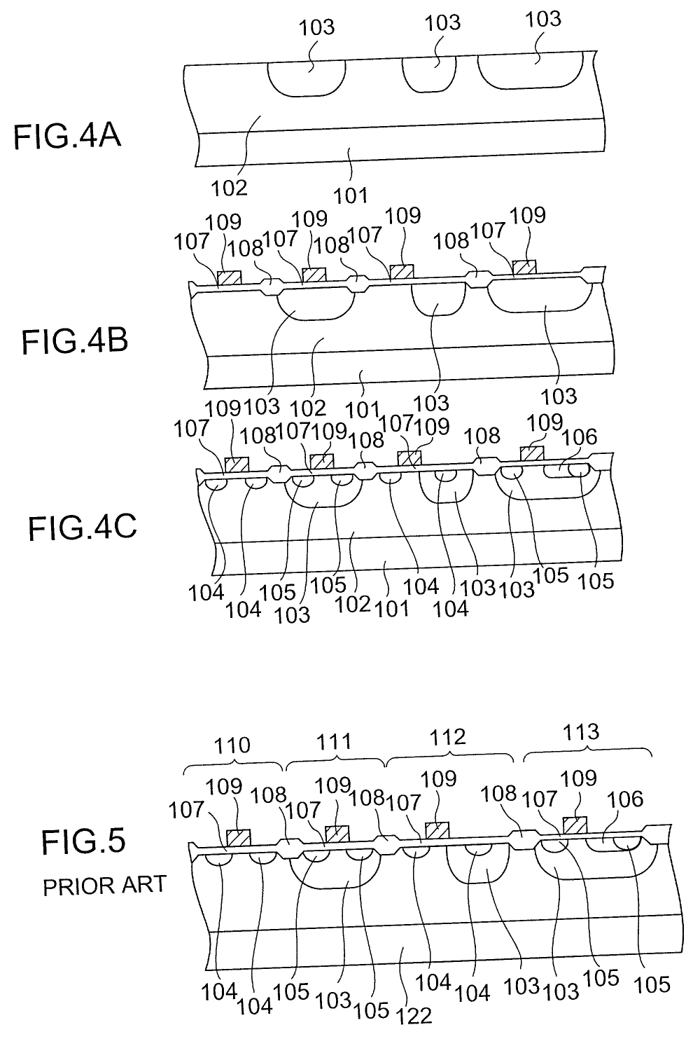

FIGS. 4A to 4C are cross-sectional views showing a method of manufacturing a complementary MOS semiconductor device in accordance with the present invention in a process order.

In FIG. 4A, after a p-type semiconductor layer 102 having boron which is p-type impurities 1×10¹⁴/cm³ to 5×10¹⁵/cm³ in concentration and about 20 to 50 μm in thickness is formed on a semiconductor substrate 101 including antimony, arsenic or phosphorus which is n-type impurities 1×10¹⁴/cm³ to 5×10¹⁵/cm³ in concentration through the epitaxial growth method, phosphorus which is n-type impurities is selectively introduced into the p-epitaxial layer 102 through the photolithography method and the ion implantation method, and then a heat treatment is conducted to form n-wells 103.

The specification of the n-type semiconductor substrate 101 may not be special, and silicon manufactured through the CZ method which is the quite standard specification may be used.

The concentration of boron in the p-epitaxial layer 102 may not be always in the above-mentioned range of from 1×10¹⁴/cm³ to 5×10¹⁵/cm³ and is preferentially set to be equal to the concentration of the p-type semiconductor substrate of the semiconductor device to which the compatibility is intended to be given. Accordingly, if the concentration of boron of the p-type semiconductor substrate of the semiconductor device to which the compatibility is intended to be given is, for example, 1×10¹⁶/cm³, the p-type epitaxial layer equal to that concentration is allowed to grow. The above-mentioned value of 1×10¹⁴/cm³ to 5×10¹⁵/cm³ merely exhibits the impurity concentration of the starting material at the time of manufacturing the general CMOS. The thickness of the p-epitaxial layer is set to such a thickness that the depletion extending from the n-well toward the substrate side is not in contact with the depletion extending from the n-type semiconductor substrate in the surface direction. In the case where the semiconductor device is formed of only the lower withstand voltage CMOS as in the second embodiment shown in FIG. 2, even if the n-well and the n-type semiconductor substrate is short-circuited by the depletion layer, there is no problem on the operation. However, as shown in the first embodiment, in the case where the higher withstand voltage CMOS is formed and the drain of the higher withstand voltage NMOS is formed of the n-well, because malfunction is induced by short-circuiting the n-well and the n-type semiconductor substrate, it is necessary to set the thickness so that those depletions are not in contact with each other in a state where the operating voltage is applied. However, this limitation is not applied to a case where another step is added to the n-well formation to form an n-type diffusion layer shallower than the n-well, and the drain of the higher withstand voltage NMOS is structured by the diffusion layer.

Then, as shown in FIG. 4B, after an element separation region 108 which is 6000 to 10000 Å in thickness has been formed through a so-called Locos method, a gate oxide film 107 which is about 100 to 500 Å in thickness is formed through the thermal oxidation method, and polycrystal silicon is coated on the oxide film which is 3000 to 5000 Å in thickness so as to form a gate 109. Then, after the phosphorus atoms which are about 1×10²⁰/cm³ in thickness are introduced into the diffusion or the polycrystal silicon through the ion implanting method, polycrystal silicon is patterned through the photolithography method and the dry etching method.

Then, as shown in FIG. 4C, the impurities are selectively introduced into a region which will form the source and drain of the MOS through the ion implantation method using as a mask the gate 109, the element separation region 108 and a photo resist patterned through the photolithography method, and a heat treatment is then conducted, to thereby form n⁺ diffusion layers 104 in the p-epitaxial layer 102 and the n-wells 103 which becomes the drain of the higher withstand voltage NMOS, and p+ diffusion layers 105 and p− diffusion layers 106 are formed in the n-wells 103. In this situation, arsenic or phosphorus is used as impurities which constitute the n+ diffusion layer 104, and its concentration is set to about 1×10²⁰/cm³. In formation of the p+ diffusion layer 105, BF₂ is used as the impurities at the time of implanting ions, and its concentration is set to about 1×10¹⁷/cm³ similarly. In formation of the p− diffusion layer 106, BF₂ is used as the impurities at the time of implanting ions similarly, and its concentration is set within a range of from about 1×10¹⁷/cm³ to 1×10¹⁸/cm³ similarly.

Subsequent to the above process, wirings connecting between the respective elements are formed by metal, and a protective film is provided, to thereby manufacture the complementary MOS semiconductor device.

FIGS. 4A to 4C show a method of manufacturing a semiconductor device in accordance with the first embodiment of the present invention shown in FIG. 1. If a process of forming the higher withstand voltage MOS shown in FIGS. 4A to 4C, that is, the formation of the p-diffusion layer 106 is omitted, the semiconductor device according to the second embodiment of the present invention shown in FIG. 2 can be formed.

The above-mentioned embodiments are directed to a case in which the p-type epitaxial layer is formed on the n-type semiconductor substrate to constitute the CMOS, but the same effect can be obtained with respect to the degree of freedom of the packaged pin arrangement even if the conductive type is inverted and the n-type epitaxial layer is formed on the p-type semiconductor substrate to constitute the CMOS.

As was described above, the polarity of the power supply lead pin can be changed while various characteristics of the semiconductor device are kept identical with those of the semiconductor device with the conventional CMOS structure through the structure and manufacturing method of the semiconductor device in accordance with the present invention.

The foregoing description of the preferred embodiments of the invention has been presented for purposes of illustration and description. It is not intended to be exhaustive or to limit the invention to the precise form disclosed, and modifications and variations are possible in light of the above teachings or may be acquired from practice of the invention. The embodiments were chosen and described in order to explain the principles of the invention and its practical application to enable one skilled in the art to utilize the invention in various embodiments and with various modifications as are suited to the particular use contemplated. It is intended that the scope of the invention be defined by the claims appended hereto, and their equivalents.

What is claimed is:

1. A complementary MOS semiconductor device, comprising:
an inverse conductive type semiconductor layer disposed on a one conductive type semiconductor substrate;
a one conductive type deep diffusion layer formed in said inverse conductive type semiconductor layer;
a one conductive type MOS transistor formed in said inverse conductive type semiconductor layer; and
an inverse conductive type MOS transistor formed in said one conductive type deep diffusion layer.

2. A complementary MOS semiconductor device, comprising:
an inverse conductive type semiconductor layer disposed on a one conductive type semiconductor substrate;
a one conductive type deep diffusion layer formed in said inverse conductive type semiconductor layer;
a one conductive type MOS transistor which is low in withstand voltage and formed in said inverse conductive type semiconductor layer; an inverse conductive type MOS transistor formed in said one conductive type deep diffusion layer; and
a one conductive type MOS transistor which is high in withstand voltage and a source or a drain of which is structured by said one conductive type deep diffusion layer.

3. A complementary MOS semiconductor device as claimed in claim 2, further comprising:
an inverse conductive type MOS transistor which is low in withstand voltage; and
an inverse conductive type MOS transistor which is high in withstand voltage, both being formed in said one conductive type deep diffusion layer.

4. A complementary MOS semiconductor device as claimed in claim 1 or 2, wherein:
said one conductive type semiconductor substrate is electrically connected to said one conductive type deep diffusion layer in which said inverse conductive type MOS transistor is formed; and
said inverse conductive type layer has such a thickness that a depletion layer extending from said one conductive type deep diffusion layer to said inverse conductive type semiconductor layer is out of contact with a depletion layer extending from said one conductive type substrate to said inverse conductive type semiconductor layer during the operation of the semiconductor device.

5. A method of manufacturing a complementary MOS semiconductor device, comprising the steps of:
forming an inverse conductive type semiconductor layer on a one conductive type semiconductor substrate;
forming a one conductive type deep diffusion layer in said inverse conductive type semiconductor layer;
forming a one conductive type MOS transistor in said inverse conductive type semiconductor layer; and
forming an inverse conductive type MOS transistor in said one conductive type deep diffusion layer.

6. A method of manufacturing a complementary MOS semiconductor device, comprising the steps of:
forming an inverse conductive type semiconductor layer on a one conductive type semiconductor substrate;
forming a one conductive type deep diffusion layer in said inverse conductive type semiconductor layer;
forming a one conductive type MOS transistor which is low in withstand voltage in said inverse conductive type semiconductor layer;
forming an inverse conductive type MOS transistor in said one conductive type deep diffusion layer; and
forming a source or a drain of a one conductive type MOS transistor which is high in withstand voltage, in said inverse conductive semiconductor layer by said one conductive type deep diffusion layer.

7. A method of manufacturing a semiconductor device as claimed in claim 5 or 6, wherein said inverse conductive semiconductor layer is formed through an epitaxial growth, to have an impurity concentration of from 1×10¹⁴/cm³ to 5×10¹⁵/cm³ and a thickness of from 20 to 50 μm.
